(19) United States
(12) Patent Application Publication
(10) Pub. No.: US 2026/0101443 A1
(43) Pub. Date: Apr. 9, 2026

(54) Structure Utilizing a PCB as an Interconnecting Carrier for Heating Elements

(71) Applicant: MEC ADDHEAT (KAIPING) CO., LTD., Kaiping City, Guangdong (CN)

(72) Inventor: CHIENCHOU CHEN, Kaiping City (CN)

(21) Appl. No.: 18/896,934

(22) Filed: Sep. 26, 2024

(51) Int. Cl. H05K 3/28; A41D 13/005; H05B 3/34

(52) U.S. Cl. CPC H05K 3/28; A41D 13/0051; H05B 3/34; H05K 2203/11; H05K 2203/1377

(57) ABSTRACT

The invention discloses a structure utilizing a Printed Circuit Board (PCB) as an interconnecting carrier for heating elements. By sandwiching a rigid PCB between upper and lower layers of hot melt adhesive film and forming an encapsulated structure through heating and melting, it achieves a rigid, non-deformable first waterproof area while forming a flexible, variable second annular waterproof buffer area on the outside. This not only enhances the durability and waterproofness of the heating components but also ensures the comfort of heated clothing. Compared to traditional flexible circuit boards, the invention offers higher mechanical strength, compatibility with various types of heating elements, and meets personalized needs, thereby improving the market adaptability and service life of heated clothing.

### TECHNICAL FIELD

The invention pertains to the field of wearable heating devices, particularly to a structure utilizing a PCB (Printed Circuit Board) as an interconnecting carrier for heating elements.

### BACKGROUND ART

In the design of wearable heated clothing, the method of connecting and securing heating elements significantly affects the product's durability, waterproofing, and comfort. Traditionally, flexible printed circuit boards (FPC) are widely used as carriers to connect heating elements, accommodating the garment's flexibility. However, while FPCs offer excellent bendability, they present several challenges in practical use:

1. Durability Concerns: The flexibility of FPCs makes them prone to cracking or damage under mechanical stresses such as washing or twisting, leading to connection failures. Moreover, FPCs require lower soldering temperatures, resulting in weaker solder joints that can suffer from issues like cold soldering or cracking over time, especially with prolonged use or environmental changes, thus compromising the heated garment's functional stability.

2. Inadequate Waterproofing: During repeated washing, moisture can easily penetrate the interior of the circuit board through the edges or solder joints, causing corrosion or short circuits. This issue is particularly severe in harsh conditions, limiting the application of heated clothing.

Refer to FIG. 1, where the copper strip 9 has multiple connection points, negatively affecting the wearer's experience due to excessive wiring inside the garment.

Refer to FIG. 2, where the flexible circuit board (FPC) 10 has a soldering temperature limit below 180° C., making it susceptible to cold soldering or brittleness. Additionally, FPCs with concentrated electronic connections are prone to stress-induced breakage during machine washing.

To address these challenges, some designs have explored replacing flexible circuit boards with rigid PCB to enhance mechanical strength and solder joint reliability. However, rigid PCBs are less compatible with the flexibility of clothing, which can reduce wearing comfort. Improper handling during fixation and encapsulation can also create stress concentrations between the rigid area and the flexible garment, leading to a poor user experience.

Therefore, the challenge of maintaining the mechanical strength and waterproof properties of rigid PCBs while ensuring the flexibility and comfort of heated clothing is the technical problem this invention seeks to solve.

### SUMMARY OF THE INVENTION

The technical problem addressed by this invention is to overcome the deficiencies in the current technology by providing a structure utilizing a PCB as a carrier for interconnecting heating elements, aiming to solve the issues of insufficient durability, poor waterproofing, and poor compatibility with flexible clothing as identified in the background.

To address these technical problems, the proposed solution of this invention is as follows:

A structure utilizing a PCB as an interconnecting carrier for heating elements, comprising:
An upper layer of hot melt adhesive film;
A lower layer of hot melt adhesive film;
A rigid PCB positioned between the upper and lower layers of hot melt adhesive film. The rigid PCB includes solder pads for connecting a power supply, a temperature controller, and at least one heating element, wherein the solder pads are connected to the corresponding electronic wiring harnesses through soldering.

The upper and lower layers of hot melt adhesive film are bonded through a heating process, forming an encapsulated structure that covers the rigid PCB and its solder pads. This encapsulated structure takes advantage of the rigidity and non-deformable nature of the rigid PCB to create a primary, non-deformable waterproof area.

Additionally, the surface area of the upper and lower layers of hot melt adhesive film is larger than that of the rigid PCB, ensuring that after the films are melted and bonded, the rigid PCB is enclosed within them, forming a secondary, flexible, and adaptable waterproof buffer area around the primary rigid waterproof area.

As a further embodiment of this invention, the rigid PCB is a rigid PCB, with its solder pads connected to electronic wiring harnesses via a high-temperature soldering process. The types of heating elements that can be connected to the rigid PCB include, but are not limited to, carbon fiber heating elements, carbon nanotube film heating elements, graphene film heating elements, and printed conductive carbon-based slurry heating elements.

As a further embodiment of this invention, the rigid PCB has a thickness of at least 0.8 mm, ensuring that the PCB possesses sufficient rigidity and durability.

As a further embodiment of this invention, the upper and lower layers of hot melt adhesive film are made from thermoplastic polyurethane (TPU) material, which ensures effective bonding and the creation of a waterproof encapsulated structure when heated.

As a further embodiment of this invention, when the structure utilizing a PCB as an interconnecting carrier for heating elements in heated clothing, the encapsulated structure allows the rigid PCB to form a waterproof area that maintains its structural integrity and functional stability during both wear and washing.

As a further embodiment of this invention, the upper surface of the upper layer of hot melt adhesive film is securely bonded to an upper fabric layer, while the lower surface of the lower layer of hot melt adhesive film is bonded to a lower fabric layer.

Compared with the prior art, this invention has the following advantages:

1. Increased durability and reliability: by utilizing a rigid PCB, the encapsulated structure forms a non-deformable primary waterproof area. Unlike traditional flexible circuit boards, the rigid PCB used in this invention offers greater mechanical strength and stability, effectively resisting external mechanical stress and bending deformation. This significantly enhances the durability and reliability of the heating components in demanding environments.

2. Enhanced waterproof performance: the surface area of the upper and lower layers of hot melt adhesive film is larger than that of the rigid PCB. After heating and melting, this design not only forms a primary waterproof area on the surface of the rigid PCB but also creates a secondary, flexible, adaptive waterproof buffer area surrounding the rigid area. This dual-layer waterproof structure provides superior protection against moisture penetration during extended wear and repeated washing, safeguarding the integrity and stability of the internal circuitry.

3. Balancing flexibility and rigidity: this invention effectively combines the rigidity of the PCB with the flexibility of the hot melt adhesive film. The result is a design that retains the protective qualities of the rigid area while incorporating a flexible area around it. This solution addresses the challenge of balancing the need for flexibility in heated clothing with the rigidity of the circuit board, enabling garments that are both comfortable and durable.

4. Broad compatibility with heating elements: The rigid PCB is compatible with a variety of heating elements, including but not limited to carbon fiber heating elements, carbon nanotube film heating elements, graphene film heating elements, and printed conductive carbon-based slurry heating elements. This invention expands the range of heating element options compared to traditional flexible circuit boards, meeting diverse user needs and enhancing market adaptability.

5. Simplified and controllable manufacturing process: The manufacturing process for this invention is straightforward and easy to control. The hot melt adhesive film is tightly bonded to the rigid PCB through a heating process, ensuring efficient and consistent product quality during production. This method is well-suited for large-scale manufacturing, helping to reduce production costs.

Further aspects and benefits of this invention will be outlined in the following description, and some will become apparent through the practical application of the invention.

### DESCRIPTION OF THE DRAWINGS

To better illustrate the technical solutions presented in the embodiments or prior art of this invention, the following is a brief description of the drawings used in these embodiments or prior art. It is important to note that the drawings described below represent only some examples of this invention. Those skilled in the art can generate additional drawings based on these without requiring inventive effort.

FIG. 1: A structural diagram illustrating the connection method using copper strips in prior art.

FIG. 2: A structural diagram illustrating the connection method of FPC flexible circuit boards in prior art.

FIG. 3: A structural diagram showing the preparation method for a single group of carbon fiber heating elements using a PCB as a heating carrier, according to this invention.

FIG. 4: A structural diagram showing the preparation method for double or multiple groups of carbon fiber heating elements using a PCB as a heating carrier, according to this invention.

FIG. 5: A schematic diagram of the carbon fiber heating element, according to this invention.

FIG. 6: A structural diagram illustrating the preparation method for two in-series heating elements made from sheet materials or sheet-structured heating materials, such as printed conductive carbon-based slurry, carbon nanotube films, or graphene films, using a PCB as a heating carrier, according to this invention.

FIG. 7: A structural diagram illustrating the preparation method for four or more in-series heating elements made from sheet materials or sheet-structured heating materials, such as printed conductive carbon-based slurry, carbon nanotube films, or graphene films, using a PCB as a heating carrier, according to this invention.

FIG. 8: A structural diagram illustrating the preparation method for two parallel heating elements made from sheet materials or sheet-structured heating materials, such as printed conductive carbon-based slurry, carbon nanotube films, or graphene films, using a PCB as the heating carrier, according to this invention.

FIG. 9: A structural diagram illustrating the preparation method for four or more parallel heating elements made from sheet materials or sheet-structured heating materials, such as printed conductive carbon-based slurry, carbon nanotube films, or graphene films, using a PCB as the heating carrier, according to this invention.

FIG. 10: A structural diagram showing the series connection method for heating elements made from printed or film-based sheet heating materials.

FIG. 11: A structural diagram showing the parallel connection method for heating elements made from printed or film-based sheet heating materials.

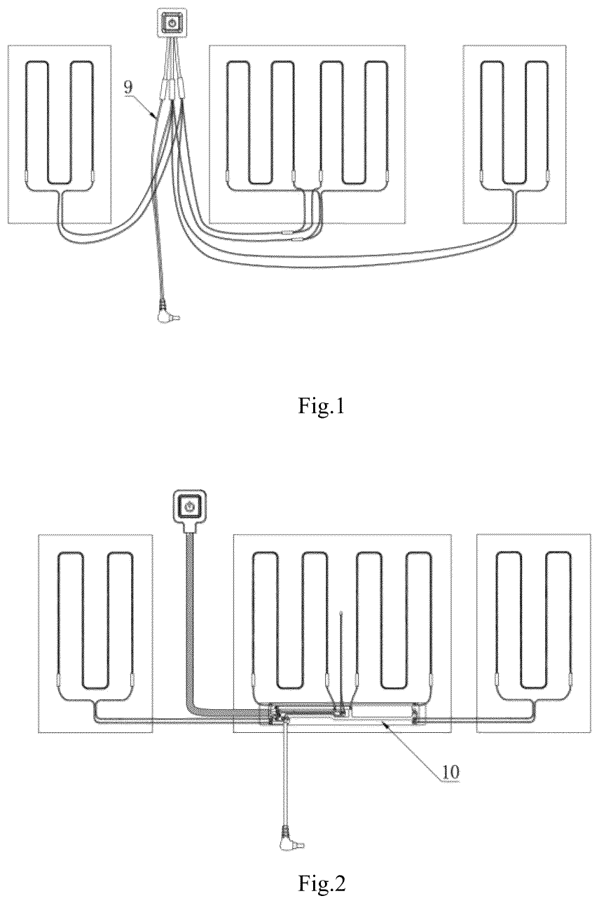

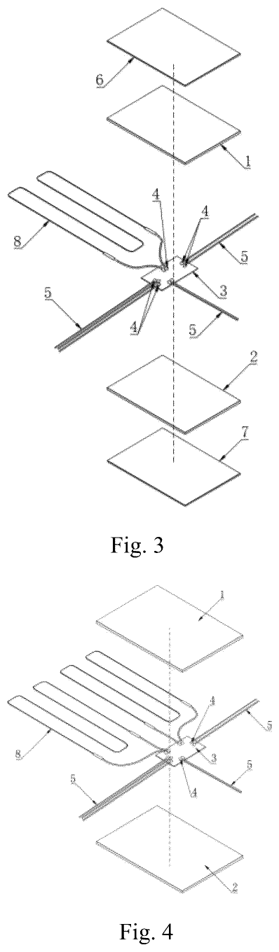

The reference numbers and their corresponding components in the figures are as follows:

upper hot melt adhesive film 1, lower hot melt adhesive film 2, rigid PCB 3, solder pad 4, electronic wiring harness 5, upper fabric layer 6, lower fabric layer 7, heating element 8, copper strip 9, and flexible circuit board (FPC) 10

### DETAILED DESCRIPTION OF THE PREFERRED EMBODIMENTS

The following provides a thorough and complete description of the technical solutions in the embodiments of this invention. It is essential to understand that the described embodiments represent only a subset of the potential implementations of this invention. Based on the provided examples, those skilled in the art can derive additional embodiments without departing from the scope of this invention.

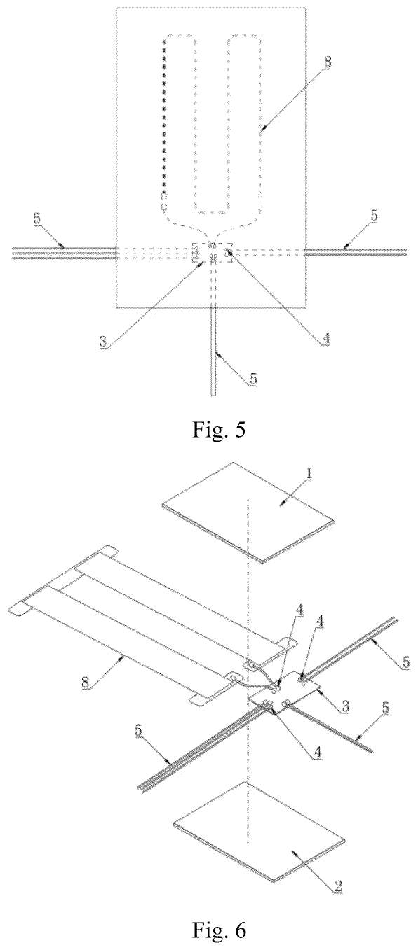

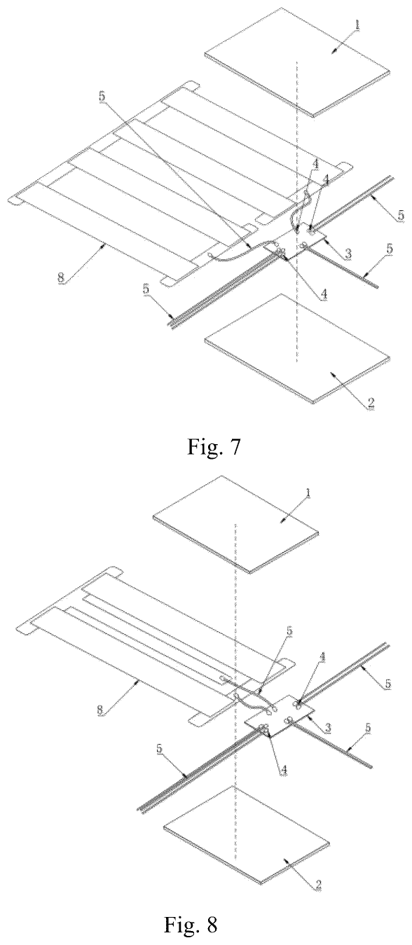

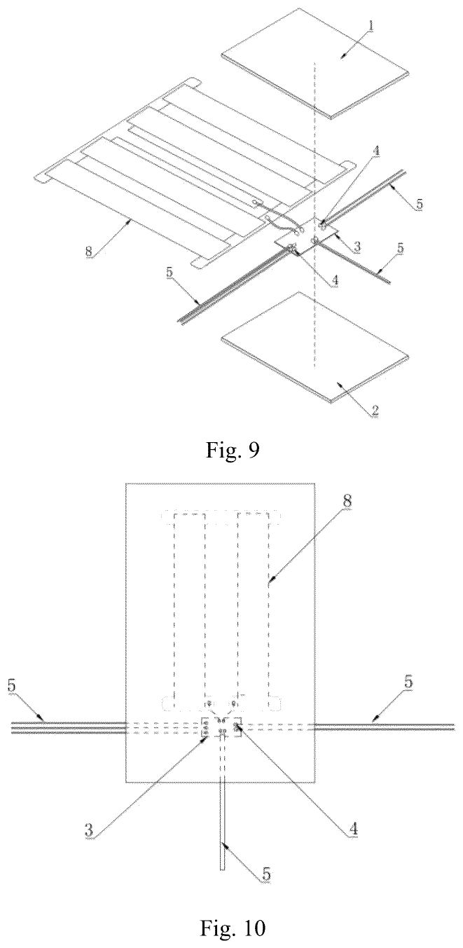

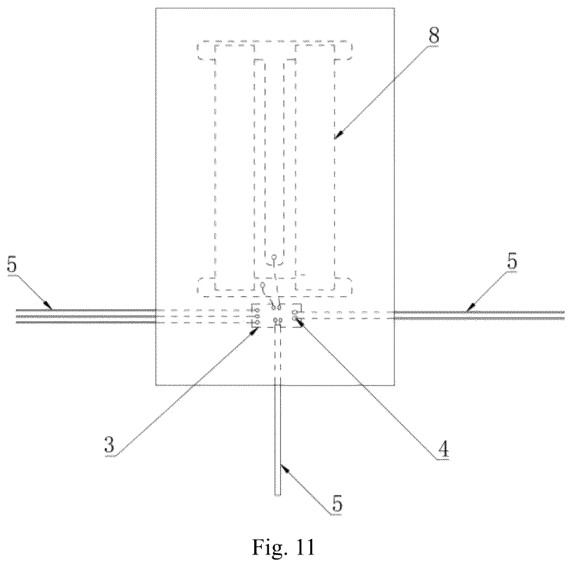

Please refer to FIGS. 3-11. In these embodiments, the invention involves a structure utilizing a PCB as an interconnecting carrier for heating elements, comprising:
an upper layer of hot melt adhesive film 1;
a lower layer of hot melt adhesive film 2;
a rigid PCB 3 positioned between the upper layer of hot melt adhesive film 1 and the lower hot melt adhesive film 2. The rigid PCB 3 includes solder pads 4 for connecting a power supply, a temperature controller, and at least one heating element 8, and the solder pads 4 are connected to the corresponding electronic wiring harness 5 through soldering.

The upper and lower layers of hot melt adhesive film 1 and hot melt adhesive film 2 are bonded through a heating and melting process, forming an encapsulated structure that covers the rigid PCB 3 and its solder pads 4. This encapsulated structure leverages the rigidity and non-deformable characteristics of the rigid PCB 3 to create a primary, non-deformable waterproof area.

Furthermore, the surface area of the upper layer of hot melt adhesive film 1 and the lower layer of hot melt adhesive film 2 is larger than that of the rigid PCB 3. After the upper layer of hot melt adhesive film 1 and the lower layer of hot melt adhesive film 2 are melted and bonded, the rigid PCB 3 is enclosed within the upper layer of hot melt adhesive film 1 and the lower layer of hot melt adhesive film 2, creating a secondary, flexible, and adaptive annular waterproof buffer area around the primary rigid waterproof area.

The rigid PCB 3 is a rigid PCB, with the solder pads 4 connected to the electronic wiring harness 5 through a high-temperature soldering process. The heating elements 8 that can be connected to the rigid PCB include, but are not limited to, carbon fiber heating elements, carbon nanotube film heating elements 8, graphene film heating elements 8, and printed conductive carbon-based slurry heating elements 8.

The thickness of the rigid PCB is set at 0.8 mm or greater to ensure that the PCB has sufficient rigidity and durability.

The upper and lower layers of hot melt adhesive film 1 and hot melt adhesive film 2 are made from thermoplastic polyurethane (TPU) material to ensure effective bonding and the formation of a waterproof encapsulated structure when heated.

When the structure utilizing a PCB as an interconnecting carrier for heating elements in heated clothing, the encapsulated structure allows the rigid PCB 3 to form a waterproof area that maintains its structural integrity and functional stability during both wear and washing.

The upper surface of the upper layer of hot melt adhesive film 1 is securely bonded to an upper fabric layer 6, while the lower surface of the lower layer of hot melt adhesive film 2 is bonded to a lower fabric layer 7.

A method for preparing the structure utilizing a PCB as an interconnecting carrier for heating Elements is disclosed, including the following steps:
Step 1: Provide a rigid PCB: A rigid PCB is provided, featuring multiple solder pads 4 for connecting a power supply, a temperature controller, and at least one heating element 8.
Step 2: Solder the electronic wiring harness: the electronic wiring harness 5 is soldered to the solder pads 4 using a high-temperature soldering process. The electronic wiring harness 5 connects the power supply, a temperature controller, and heating elements 8.
Step 3: Position the hot melt adhesive film: the rigid PCB is positioned between the upper layer of hot melt adhesive film 1 and the lower layer of hot melt adhesive film 2. The surface area of the upper layer of hot melt adhesive film 1 and the lower layer of hot melt adhesive film 2 is larger than that of the rigid PCB.
Step 4: Heat and melt: the upper layer of hot melt adhesive film 1 and the lower layer of hot melt adhesive film 2 are heated, causing them to melt and bond to the rigid PCB, forming an encapsulated structure that covers the rigid PCB and its solder pads 4.
Step 5: Form waterproof areas: the encapsulated structure, utilizing the rigidity of the PCB, forms a primary, non-deformable waterproof area. Simultaneously, a secondary, flexible, and adaptive annular waterproof buffer area is formed around the rigid area.

In Step 1, the surface of the rigid PCB undergoes an anti-oxidation treatment to enhance the durability and environmental adaptability of the circuit board.

In Step 2, the high-temperature soldering process is conducted within a temperature range of 240° C. to 300° C., ensuring the reliability of the soldering and the mechanical strength of the solder joints.

In Step 3, the positioning of the rigid PCB is pre-treated to ensure the surface is free from dust and oil, optimizing the adhesion between the hot melt adhesive film and the PCB.

This invention highlights the key differences between using a rigid PCB and an FPC as carriers for heating elements in heated garments:

| | When Using FPC for | When Using PCB for |
|---|---|---|
| | Connection | Connection |
| Temperature | 120° C.-180° C., not | 240° C.-300° C., resistant to |
| Resistance | resistant to high- | high-temperature soldering |
| | temperature soldering | |
| Soldering | Low reliability; | High reliability; |
| Reliability | Low-temperature soldering | High-temperature standard |
| | in shorter time is required, | soldering is supported, |
| | which can lead to cold | ensuring stable and |
| | solder joints and fake | reliable soldering |
| | soldering | |
| Size: | Size varies according to the | Regardless of the heating |
| | heating element size; if | element size, the PCB is |
| | greater than 10 cm or 16 | smaller than or equal to |
| | cm, the FPC size is large | 5.0 cm, relatively small |
| | | PCB size |
| Thickness | Board thickness is 0.25 mm | Board thickness is 0.8 mm |
| | or less, showing weakness | or more, three times |
| | and susceptibility to | thicker, indicating stronger |
| | damage | durability |
| Repeated | FPC connects the multi- | The rigid PCB is fixed |
| Washing | directional heating element | within the heating |
| Durability | wires and simultaneously | elements, and although |
| | links the electronic wiring | there are several strong |
| | harness for temperature | electronic wires pulling on |
| | control, as well as the | it, the rigid structure of the |
| | power input harness for | PCB prevents it from being |
| | the battery. As a result, | displaced. As a result, the |
| | within the garment, the | movement within the |
| | FPC is surrounded by | garment is concentrated |
| | several strong electronic | only at the center of the |
| | wires pulling on the FPC | PCB board, while the |
| | board, causing movement | electronic wires move |
| | and making it prone to | around it, thereby |
| | tearing the solder pads at | maintaining the integrity of |
| | the connection points or | the PCB board. |
| | breaking the FPC board. | |

### Example 1

In practical applications of wearable heated garments, flexible circuit boards (FPC) are commonly used as carriers to connect heating elements 8 due to their bendable nature. However, over extended use, these garments often face mechanical twisting, repeated washing, and environmental changes, which can cause FPCs to become susceptible to damage, cold solder joints, or even breakage. Such issues lead to failures in the connections between heating elements 8, directly impacting the functional stability of the heated garment and diminishing the user experience.

To overcome this problem, this example introduces the use of a rigid PCB 5 as the carrier for connecting heating elements 8. Through innovative encapsulation technology, a structure is created that successfully balances waterproofing, durability, and flexibility.

The implementation steps are as follows:

First, a rigid PCB 5 is selected to serve as the connecting carrier for heating elements 8. This PCB 5 is pre-equipped with multiple solder pads 4 for connecting heating elements 8, power input wires, and temperature controllers. Given the high mechanical strength of the rigid PCB, it effectively resists external mechanical stress, ensuring circuit stability during prolonged wear and washing.

Next, the electronic wiring harness 5 is securely soldered to the solder pads 4 on the PCB 5 using a high-temperature soldering process. This process, performed within a temperature range of 240° C. to 300° C., ensures that the solder joints have sufficient mechanical strength to prevent cold solder joints or breakage caused by temperature fluctuations or external forces during use.

After soldering, the rigid PCB 5 is sandwiched between the upper layer of hot melt adhesive film 18 and the lower layer of hot melt adhesive film 22. Notably, the surface area of the upper and lower layers of hot melt adhesive films 18, 22 is larger than that of the rigid PCB 5. This design ensures that during the subsequent heating and melting process, the hot melt adhesive film fully encapsulates the rigid PCB 5 and extends outward, forming a flexible region.

The assembled PCB 5 and hot melt adhesive film combination is then placed in heating equipment for the heating and melting process. During heating, the hot melt adhesive film is melted and bonded to the rigid PCB 5, forming an encapsulated structure. This process leverages the rigidity of the rigid PCB 5 to create a primary, non-deformable waterproof area 12 on its surface. Additionally, due to the extensibility of the hot melt adhesive film, a secondary, flexible, and adaptive annular waterproof buffer area 13 is formed around the rigid PCB 5.

The final encapsulated heating component not only ensures the protection and durability of the circuit board in the rigid area but also effectively maintains the flexibility and comfort of the heated garment through the flexible area. Compared to traditional FPC circuit boards, this structural design significantly enhances the waterproof performance of the heated garment, especially in scenarios involving multiple washes or humid environments, effectively preventing moisture penetration and ensuring the long-term operation of the garment.

Through the technical solution presented in this example, the heated garment not only achieves significant improvements in durability and waterproofing but also overcomes the compatibility issues between rigid circuit boards 3 and flexible garments, greatly enhancing the user's wearing experience.

### Example 2

In the design of wearable heated garments with multiple heating elements 8, traditional designs often use flexible circuit boards (FPC) for connections due to their ability to adapt to the garment's bending characteristics. However, as the number of heating elements 8 increases, the limitations of FPCs become more pronounced. Particularly when connecting multiple different types of heating elements 8, FPCs are prone to issues such as cold solder joints, solder joint cracking, and breakage during multiple washes and wear due to insufficient solder joint strength and lower mechanical strength. Moreover, the poor temperature resistance of FPCs significantly restricts their reliability and durability when using different types of heating elements 8.

To address these challenges, this example proposes using a rigid PCB 5 as the connecting carrier for heating elements 8, combined with a multilayer hot melt adhesive film encapsulation process, to ensure reliable connections between multiple heating elements 8 and enhance the overall durability and waterproofing of the structure.

The application steps are as follows:

First, a suitable rigid PCB 5 is selected, featuring multiple solder pads 4 designed to connect different types of heating elements 8. In this example, the types of heating elements 8 include carbon fiber heating elements, carbon nanotube film heating elements 8, and graphene film heating elements 8. Because the rigid PCB 5 can withstand higher soldering temperatures (240° C. to 300° C.), the reliability of the solder joints is greatly improved, effectively preventing the cold solder joints and solder joint cracking issues commonly associated with flexible circuit boards when connecting different types of heating elements 8.

Next, the soldered rigid PCB 5 is sandwiched between the upper and lower layers of hot melt adhesive film 18, 22. The surface area of the hot melt adhesive film is designed to be larger than that of the rigid PCB 5, allowing the rigid PCB 5 to be fully encapsulated by the hot melt adhesive film during the encapsulation process, creating a flexible region on the outside. This design not only provides a rigid, waterproof protective area but also ensures the comfort of the heated garment through the flexible region on the outside.

Following this, the upper and lower layers of hot melt adhesive films 18, 22 are melted and bonded to the rigid PCB 5 using a heating and melting process. The melted hot melt adhesive film tightly encapsulates the rigid PCB 5 and solder pads 4, forming a robust waterproof encapsulation structure in the rigid area and a flexible, adaptive waterproof area in the outer region of the PCB. This design effectively addresses the compatibility issues of integrating multiple different types of heating elements 8 within the same heated garment, ensuring reliable connections between heating elements 8 and maintaining the overall flexibility of the garment.

By applying this example, not only is a stable connection and operation of multiple heating elements 8 achieved, but the service life and user experience of the heated garment are also significantly enhanced. Compared to traditional designs using flexible circuit boards, this example demonstrates substantial advances in mechanical strength, soldering reliability, waterproofing, and flexible compatibility, ensuring the widespread applicability of the heated garment in various scenarios.

In this invention, unless otherwise explicitly specified and defined, terms such as “installation”, “setup”, “connection”, “fixation”, “screwing”, and other similar terms should be understood in a broad sense. For example, they can refer to fixed connections, removable connections, or integral connections; they can refer to mechanical connections or electrical connections; they can refer to direct connections or indirect connections through intermediaries; they can refer to communication within two elements or the interaction relationship between two elements. Unless explicitly defined otherwise, those skilled in the art should understand the specific meaning of these terms in the context of this invention.

It is evident to those skilled in the art that this invention is not limited to the details of the exemplary embodiments described above and that the invention can be implemented in other specific forms without departing from the spirit or essential characteristics of the invention. Therefore, the embodiments should be considered illustrative rather than restrictive, and the scope of the invention is defined by the appended claims rather than the foregoing description. It is intended that all modifications within the meaning and range of equivalency of the claims are included within the scope of this invention.

1. A structure utilizing a PCB as an interconnecting carrier for heating elements, characterized by:
An upper layer of hot melt adhesive film;
A lower layer of hot melt adhesive film;
A rigid PCB positioned between the upper and lower layers of hot melt adhesive film. The rigid PCB includes solder pads for connecting a power supply, a temperature controller, and at least one heating element, and the solder pads are connected to the corresponding electronic wiring harnesses through soldering.
The upper and lower layers of hot melt adhesive film are bonded through a heating process, forming an encapsulated structure that covers the rigid PCB and its solder pads. The encapsulated structure leverages the rigidity and non-deformable nature of the rigid PCB to create a primary waterproof area that remains stable and unchanged.
Additionally, the surface area of the upper and lower layers of hot melt adhesive film is larger than that of the rigid PCB. This design ensures that after the films are melted and bonded, the rigid PCB is enclosed within them, creating a secondary, flexible, and adaptive waterproof buffer area around the primary, rigid waterproof area.

2. The structure utilizing a PCB as an interconnecting carrier for heating elements according to claim 1, characterized in that the rigid PCB is a rigid PCB, with its solder pads connected to electronic wiring harnesses via a high-temperature soldering process. The types of heating elements that can be connected to the rigid PCB include, but are not limited to, carbon fiber heating elements, carbon nanotube film heating elements, graphene film heating elements, and printed conductive carbon-based slurry heating elements.

3. The structure utilizing a PCB as an interconnecting carrier for heating elements according to claim 2, characterized in that the rigid PCB has a thickness of at least 0.8 mm to ensure sufficient rigidity and durability.

4. The structure utilizing a PCB as an interconnecting carrier for heating elements according to claim 1, characterized in that the upper and lower layers of hot melt adhesive film are made of thermoplastic polyurethane material, ensuring effective bonding and the formation of a waterproof encapsulated structure when heated.

5. The structure utilizing a PCB as an interconnecting carrier for heating elements according to claim 1, characterized in that when the structure utilizing a PCB as an interconnecting carrier for heating elements in heated clothing, the encapsulated structure allows the rigid PCB to form a waterproof area that maintains its structural integrity and functional stability during both wear and washing.

6. The structure utilizing a PCB as an interconnecting carrier for heating elements according to claim 1, characterized in that the upper surface of the upper layer of hot melt adhesive film is securely attached to an upper fabric layer, and the lower surface of the lower layer of hot melt adhesive film is securely attached to a lower fabric layer.
